(19) United States
(12) Patent Application Publication
(10) Pub. No.: US 2019/0243723 A1
(43) Pub. Date: Aug. 8, 2019

(54) BACKUP OPERATIONS FROM VOLATILE TO NON-VOLATILE MEMORY

(71) Applicant: Micron Technology, Inc., Boise, ID (US)

(72) Inventor: Gary R. Van Sickle, Arden Hills, MN (US)

(21) Appl. No.: 16/123,401

(22) Filed: Sep. 6, 2018

Related U.S. Application Data
(60) Provisional application No. 62/628,135, filed on Feb. 8, 2018.

(51) Int. Cl. G06F 11/14; G06F 3/06; G11C 5/04

(52) U.S. Cl. CPC G06F 11/1461; G06F 3/0659; G06F 11/1466; G06F 11/1464; G11C 5/04

(57) ABSTRACT

Devices and techniques are disclosed herein for performing a backup operation on a memory system in response to a trigger event. The memory system can comprise a processing device, a group of volatile memory cells, and a group of non-volatile memory cells. The processing device can be configured to perform internal backup operations in response to a trigger event, comprising: determining, in response to the trigger event, if the memory system is in self-refresh mode; and in response to determining that the memory system is not in self-refresh mode: storing an indication readable by a host that the memory system is not in self-refresh mode; and performing an internal backup operation, comprising saving at least a portion of data stored on the group of volatile memory cells to the group of non-volatile memory cells.

### CLAIM OF PRIORITY

This application claims the benefit of priority under 35 U.S.C. § 119(e) of U.S. Provisional Patent Application Ser. No. 62/628,135, entitled “SELF REFRESH BYPASS,” filed on Feb. 8, 2018, which is herein incorporated by reference in its entirety.

### TECHNICAL FIELD

Embodiments of the disclosure relate generally to memory systems, and more specifically, to backup operations from volatile to non-volatile memory (NVM).

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data at the memory components and to retrieve data from the memory components.

Volatile memory can require power to maintain data and includes random-access memory (RAM), dynamic random-access memory (DRAM), and synchronous dynamic random-access memory (SDRAM), among others. Non-volatile memory can provide persistent data by retaining stored data when not powered and can include NAND flash memory. NOR flash memory, read only memory (ROM), Electrically Erasable Programmable ROM (EEPROM), Erasable Programmable ROM (EPROM), and resistance variable memory such as phase change random access memory (PCRAM), resistive random-access memory (RRAM), and magnetoresistive random access memory (MRAM), cross-point array of memory, among others.

Memory cells are typically arranged in a matrix or an array. Multiple matrices or arrays can be combined into a memory device, and multiple devices can be combined to form a storage volume of a memory system, such as a solid-state drive (SSD), a Universal Flash Storage (UFS™) device, a MultiMediaCard (MMC) solid-state storage device, an embedded MMC device (eMMC™), etc.

A memory system can include one or more processors or other memory controllers performing logic functions to operate the memory devices or interface with external systems. The memory matrices or arrays can include a number of blocks of memory cells organized into a number of physical pages. The memory system can receive commands from a host in association with memory operations, such as read or write operations to transfer data (e.g., user data and associated integrity data, such as error data and address data, etc.) between the memory devices and the host, erase operations to erase data from the memory devices, or perform one or more other memory operations.

### BRIEF DESCRIPTION OF THE DRAWINGS

The present disclosure will be understood more fully from the detailed description given below and from the accompanying drawings of various embodiments of the disclosure.

FIG. 1 illustrates an example of a non-volatile dual in-line memory module (NVDIMM) device, in accordance with some examples of the present disclosure.

FIG. 2 illustrates an example method for performing, using a processing device of a memory system, an internal backup operation on the memory system.

FIG. 3 illustrates an example method for triggering a catastrophic save operation (CSAVE) in a memory system using a timer, in accordance with some examples of the present disclosure.

FIG. 4 illustrates an example computer system in which embodiments of the present disclosure may operate.

### DETAILED DESCRIPTION

Aspects of the present disclosure are directed to performing backup operations from volatile memory to non-volatile memory (NVM) of a memory system including a memory sub-system. A memory sub-system is also herein referred to as a “memory device”. Examples of a memory sub-system is a storage system, such as a solid-state drive (SSD) and a non-volatile dual in-line memory module (NVDIMM). In some embodiments, the memory sub-system is a hybrid memory/storage sub-system having both volatile and non-volatile memory sub-systems. In general, a host system can utilize a memory sub-system that includes one or more memory components. The host system can provide data to be stored at the memory sub-system and can request data to be retrieved from the memory sub-system.

Memory systems can include multiple memory devices on a single module, such as single or dual in-line memory modules (SIMM or DIMM). One form of main memory includes a NVDIMM. The NVDIMM is a memory sub-system that operates at volatile-memory speeds, but retains the power-loss data-retention functionality of non-volatile memory. In certain examples, the NVDIMM can include a memory controller, volatile memory (e.g., synchronous dynamic random-access memory (SDRAM)), non-volatile memory NAND flash memory), and a backup power source, typically a battery or a capacitor configured to provide backup power to the memory module, such as after main power loss (e.g., power loss from a host). In an example, each of the volatile memory and the non-volatile memory of the NVDIMM can include multiple memory components (e.g., a number of dies or logical units (LUNs)), each including device logic or a device controller or processor separate from the memory controller of the NVDIMM. The NVDIMM can use volatile memory during normal operation. Upon main power loss (e.g., host power loss), or in response to a received instruction from a host, the NVDIMM can perform an internal backup or catastrophic save operation (CSAVE), writing the contents of the volatile memory, or a portion thereof, to non-volatile memory, and in certain examples, managing the non-volatile memory during main power loss, using the backup power source.

The Joint Electron Device Engineering Council (JEDEC) has promulgated several standards pertaining to DIMMs, including Double Data Rate (DDR) memory interfaces and NVDIMMs that use DDR interfaces. NVDIMM devices include a number of implementations, including NVDIMM-N, N VDIMM-F, NVDIMM-P, NVDIMM-X, or one or more other NVDIMM devices. For example, NVDIMM-N is a family of JEDEC standards in which a DIMM includes flash storage and a memory controller in addition to DRAM or SRAM volatile memories. JEDEC standard 245B.01 (JESD245B.05) for Byte Addressable Energy Backed Interface (BAEBI) provides a number of implementation and interaction details. In an example, the NVDIMM disclosed herein can include an NVDIMM-N device, or one or more other NVDIMM implementation.

Operation of the NVDIMM can be controlled by the memory controller, in response to instructions from a host or one or more other events. The memory controller can include an application specific integrated circuit (ASIC), a field programmable gate array (FPGA), or other processing circuitry, arranged or programmed to manage data transfers between the DRAM or SDRAM volatile portion of the module to the flash non-volatile portion (e.g., the storage backing the DRAM or SDRAM memory). The host can communicate with the NVDIMM through one or more communication interfaces, such as a packet switched Inter-Integrated Circuit (I2C, I²C, or IIC) communication bus between the memory controller and the host, a multi-pin serial communication bus (e.g., a DDR version 4 (DDR4) memory interface, etc.) for memory operations between the NVDIMM and the host, or one or more other communication interfaces, etc.

I2C communication can provide a flexible, efficient solution directly read or write to registers in, or otherwise communicate to, a memory controller. However, whereas the throughput of a typical serial communication interface in a volatile memory device, such as DDR4 or other multi-pin serial communication interfaces, can be 1,600-3,200 megabits (Mbits) per second (or more), I2C communication is much slower, for example, in the order of 100-400 kilobits (Kbits) per second.

A CSAVE operation can be triggered using a command from a host, such as an I2C command from the host to the memory controller, or a signal on a physical signal line (e.g., a SAVE_n line) of the serial communication interface (e.g., a DDR4 communication bus, etc.), etc. When the NVDIMM receives the CSAVE operation, a bit in a CSAVE_INFO register can be set to indicate the trigger source (e.g., the SAVE_n or I2C command). The bit can include a START_CSAVE bit, and the CSAVE_INFO register can include a NVDIMM_FUNC_CMD register. In an example, a register can be used to indicate the source of the trigger. For example, a SAVE_n Trigger bit in a CSAVE_TRIGGER_SUPPORT register can be used to indicate that the CSAVE operation was triggered from a SAVE_n trigger source on the serial communication interface DDR4).

Upon restart of the NVDIMM, or a system including the NVDIMM, such as after main power loss, one or more of the communication interfaces, such as the serial, multi-pin communication bus (e.g., DDR4, etc.) between the host and the NVDIMM, can be in a known state. In CSAVE situations where the host is in control, such as when providing an I2C or SAVE_n command to perform a CSAVE operation, the host can place the communication interface in the required state. However, in other examples, such as when the host or the memory controller becomes non-responsive, the state of the communication interface may be unknown (e.g., to the NVDIMM). Certain standards require that the NVDIMM fail a CSAVE operation if the state of the communication interface is not in a specific, known state. For example, a traditional CSAVE operation will fail if the host has not placed the memory controller in self-refresh mode, or the memory controller, volatile memory, or communication interface are not otherwise in self-refresh mode (e.g., where the DRAM or DDR4 communication interface are idle).

The present inventor have recognized, among other things, that it can be advantageous to backup, write, or save at least a portion of the data stored in volatile memory (e.g., critical data, some data, or all data, etc.) to non-volatile memory when the host freezes, locks up, or otherwise becomes non-responsive or deviates from normal operation, even when host power is present and valid, and, in certain examples, when the state of the communication interface is known or not known (e.g., when one or more of the memory controller, volatile memory, or communication interface are not in self-refresh mode). In example embodiments of the present disclosure, in a restore or recovery situation, some data, for either recovery or diagnosis, may be better than no data. Further, a CSAVE operation may still he performed if the memory system, or the volatile memory, is not in self-refresh mode (e.g., after a number of re-checks for self-refresh mode after a period of time).

Further, as the state of the communication bus may not be known when such backup, write, or save occurs, one or more registers can be used to signify to the host or a user that such backup, write, or save occurred, why such backup, write, or save occurred, or that the NVDIMM has the capability to perform such backup, write, or save, for example, when the communication bus is in an unknown state, when the communication bus is a state adverse to typical CSAVE functionality, or when a self-refresh mode for the NVDIMM is not enabled, etc.

In an example, a timer (e.g., a watchdog timer) can be implemented between the host and the memory controller, such as in a timer register in the memory controller. In an example, the timer register can include a HOST_TIMEOUT_CSAVE_TIMEOUT register, e.g., at page 15/offset 0x80 (P15:0x80). The timer register can be an 8-bit register [7:0] with read/write access. The timer can be set, programmed, initiated, reset, or otherwise controlled by one or both of the host or the memory controller. In an example, the timer can be controlled by the host. In other examples, the memory controller can infer host control through other host actions or instructions.

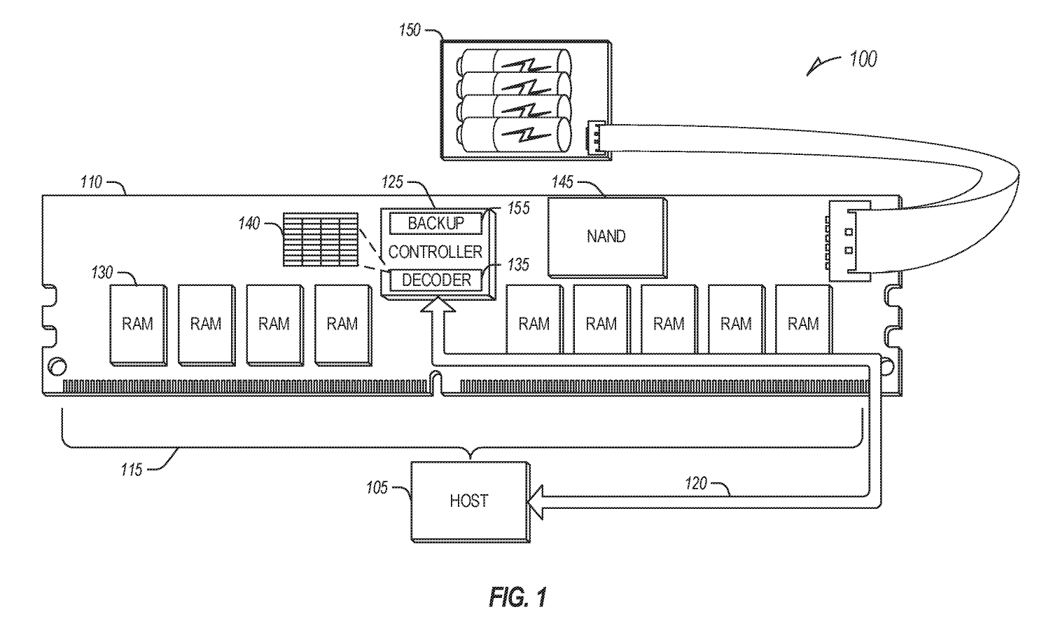

FIG. 1 illustrates an example system 100 including a host 105 and an NVDIMM 110. The host 105 can include a host processor, a central processing unit, or one or more other processor, such as in an electronic (or host) device. The NVDIMM 110 includes a controller 125 (e.g., a memory controller, a processing device, etc.), a volatile storage portion 130 (e.g., RAM), a non-volatile storage portion 145 (e.g., NAND), a first interface 120 (e.g., an I2C bus), and a second interface 115 (e.g., a DDR interface). In an example, the NVDIMM 110 can conform to a JEDEC NVDIMM-N family of standards. In other examples, the NVDIMM 110 can conform to one or more other NVDIMM standards.

The volatile portion 130 (e.g., a volatile memory array, group of memory cells, etc.) can include one or more DRAM or SRAM integrated circuits (ICS) to store data for read or write operations of the host 105 via the second interface 115. The non-volatile storage portion 145 (e.g., a non-volatile memory array, group of memory cells, etc.) can be implemented in any storage technology that does not require power in order to maintain state. Example non-volatile storage technologies can include NAND flash, NOR flash, storage class memory (e.g., phase change memory), magnetic storage, and the like.

The host 105 can communicate with the controller 125 using the first interface 120 to perform a variety of operations within the NVDIMM 110, such as to perform a CSAVE, or to enable or disable additional functionality of the controller 125, such as a timer-based CSAVE trigger, as described herein. In an example, one or more of the host 105 or the controller 125 can include a backup component 155 (e.g., circuitry, processing device, dedicated logic, programmable logic, firmware, etc.) configured to perform or control one or more of the backup operations (e.g., CSAVE, etc.) described herein. The controller 125 can be implemented as electronic hardware, such as an FPGA, ASIC, digital signal processor (DSP), or other processing circuitry, and can execute instructions (e.g., firmware) on the electronic hardware to perform the operations.

The first interface 120 can include an I2C bus. The host 105 can use the I2C bus, and I2C communication, to set registers in the controller 125. For example, the host 105 can set a specific register such that a specific bit in that register is changed from a zero into a one. When this bit value change corresponds to execution of a command, the controller 125 can perform the command in response to the bit modification. If the command has arguments, the host 105 can set the registers corresponding to the arguments.

In an example, the controller 125 can be configured to receive (e.g., at a decoder 135 of the controller 125) an encoded message, such as over the first interface 120. Where the first interface 120 operates in accordance with an I2C family of standards, the message encoding can be the I2C marketization of the message. The decoder 135 can be arranged to obtain a decoded message that includes an attribute. In an example, the attribute can be a name of a command. A command name can be in a payload of a packetized message. In an example, the attribute is an address. An address can be in a header of a packetized message. In an example, the address can include a page designator. In an example, the address can include both a page designator and an offset.

The decoder 135, or the controller 125, can be arranged to compare the attribute to a set of attributes—that correspond to an advertised status of the memory package—to determine that the attribute is in the set of attributes. Here, advertised status means a status of the NVDIMM 110 that is observable outside of the NVDIMM 110. For example, a status bit a “busy bit”), or register, that is readable by the host 105 is an advertised status. In an example, the advertised status indicates whether there is an operation in progress for the controller 125. In an example, the advertised status indicates a type of the operation that is in progress.

The attribute to set of attributes comparison can be implemented several ways. In an example, the set of attributes are stored in a table 140 or other data structure. Here, the decoder 135 or the controller 125 can be arranged to match the attribute to a record in the table 140 to determine that the attribute is in the set of attributes. If no match exists, then the attribute does not correspond to an advertised status of the NVDIMM 110. In an example, the set of attributes can be defined by the JEDEC BAEBI family of standards, such as the JESD245B.01 standard.

The NVDIMM 110 can optionally include a power source 150 separate from host power. The power source 150 can be incorporated into the NVDIMM package, or connected to the NVDIMM package (as illustrated). The power source 150 can provide power to enable the controller 125 to move data from the volatile portion 130 to the non-volatile portion 145 in case of host power failure.

In example embodiments of the present disclosure, the timer can start at 0 seconds at every power-on. A non-zero write to the timer register can start (or if already started, reset or restart) the timer to the value of the non-zero write. In an example, the units of the value can be in seconds. At 1-second granularity, one 8-bit I2C register can provide a timer to be set from 1 second to 255 seconds (4.25 minutes), counting up or down (e.g., once per second, etc.). In an example, a write of zero to the timer register can stop the timer. In certain examples, a read of the timer register can reset the timer, or return the timer to the previously written value.

In an example, once set by the host, or in response to a host command or other instruction, the memory controller can decrement the timer register, e.g., once per second. When the countdown reaches 0, the memory controller can initiate a CSAVE on the NVDIMM.

In an example, the HOST_TIMEOUT_CSAVE_TIMEOUT register can have the following attributes;

TABLE 1
HOST_TIMEOUT_CSAVE_TIMEOUT Attributes

| Definition | Access | Mand | Persist | Default |
|---|---|---|---|---|
| [7:0]: Timeout | RW | N/A | N | 0 |

In the attribute tables herein, “Access” is host access property (read/write (RW), read only (RO), or write only (WO)), “Mand” is mandatory (Y or N); “Persist” is persistent through power cycles (Y or N); and “Default” is the default value of the register.

One or both of the host or the memory controller can be configured to reset the timer before the timer expires (e.g., before the time on the timer expires, or before the time reaches the set, programmed, or default time, depending on whether the timer is counting up or down, etc.). If the timer expires without being reset or otherwise disabled by the host or the memory controller, the NVDIMM can perform a CSAVE operation, saving at least a portion of the data stored in volatile memory to non-volatile memory. In an example, the timer register can have read/write capabilities, and can be updated off an internal clock, or one or more other instructions or clock received from the host.

In certain examples, capability of the NVDIMM to perform such timer functionality can be communicated to the host or to a user, and, when such timeout occurs, that a backup, write, or save (e.g., CSAVE) occurred in response to expiration of the timer, using one or more values in a register. In an example, the timer functionality can be communicated to the host or to the user using a value in a first register (e.g., a vendor-specific, support register, etc.), and that the backup, write, or save (e.g., CSAVE) occurred in response to expiration of the timer can be communicated to the host or to the user using a value in a second register (e.g., a vendor-specific, info register, etc.).

In an example, the first register (e.g., a support register) can include a VENDOR_CSAVE_TRIGGER_SUPPORT register (e.g., at page 0/offset 0x16 (p0:0x16)). In certain examples, the first register can indicate which CSAVE triggers are supported by the memory system. The first register is not duplicative of the contents of a CSAVE_TRIGGER_SUPPORT register, but supplementary to it, providing indications of further CSAVE trigger support beyond that provided by the CSAVE_TRIGGER_SUPPORT register defined by JEDEC. In an example, a bit that is set in the first register can indicate that the memory system supports the corresponding trigger (e.g., a watchdog timer CSAVE trigger, etc.), or that the corresponding trigger is enabled, whereas a bit that is clear in the first register can indicate that the memory system does not support the corresponding trigger, or that the corresponding trigger is disabled. In other examples, a first bit can indicate that the memory system is capable to perform the corresponding trigger, and a second bit can enable or disable the corresponding trigger.

In an example, the second register (e.g., an info register) can include a VENDOR_CSAVE_INFO register (e.g., at page 15/offset 0x82 (P15:0x82)). The second register is not duplicative of the CSAVE_INFO register, but supplementary to it, providing further indications that the last CSAVE event was triggered in response to the function indicated in the first register. In an example, if the first register defines multiple triggers, the second register can provide an indication of which trigger resulted in the CSAVE event. If a CSAVE event is triggered by an event different than the indication provided in the first register, for example, if the CSAVE event is triggered by an I2C or SAVE_n command, the second register will provide an indication that the functionality defined in the first register did not trigger the previous CSAVE event. For example, if a bit (e.g., bit 3) of the second register is set, the last CSAVE operation was triggered by the functionality defined in the first register. In an example, the bit can be cleared once a CSAVE event is triggered by a different instruction or event.

In an example, the first and second registers can be 8-bit registers [7:0], and can include vendor-specific registers, the location of which can be reserved or defined in a standard (e.g., a JEDEC standard) as vendor-specific registers, but the function of which is not defined in such standard. In other examples, the function of the support and info registers can be implemented using different bits in a single register, or using specific bits in separate registers.

In an example, the VENDOR_CSAVE_TRIGGER_SUPPORT and VENDOR_CSAVE_INFO registers can have the following attributes:

TABLE 2
VENDOR_CSAVE_TRIGGER_SUPPORT Attributes

| Definition | Access | Mand | Persist | Default |
|---|---|---|---|---|
| [1:0]: Reserved | RO | N/A | Y | 0x04 |
| [2]: Host Timeout | | | | |
| CSAVE Trigger | | | | |
| [7:3]: Reserved | | | | |

TABLE 3
VENDOR_CSAVE_INFO Attributes

| Definition | Access | Mand | Persist | Default |
|---|---|---|---|---|
| [2:0]: Reserved | RO | N/A | Y | 0x00 |
| [3]: Triggered by Host | | | | |
| Timeout CSAVE | | | | |
| Timeout | | | | |
| [7:4]: Reserved | | | | |

When a CSAVE operation does occur, the memory system (e.g., the NVDIMM) can disconnect the volatile memory (e.g., DRAM) logically, if not physically, from the host. For example, in self-refresh mode, the memory controller can disable input buffers to the volatile memory (e.g., except clock and reset signals, etc.). In self-refresh mode, the volatile memory can maintain its data, while power is maintained, even after some or all of the data in the volatile memory (e.g., critical data, some data, or all data, etc.) has been backed up, written, or saved, to the non-volatile memory.

In an example, DDR CKE0/CKE1 signals are asserted low when the volatile memory (e.g., DRAM) is in self-refresh mode. Such signals are presented as bits [5:4] in the IPHI_NVCM_MISC_STATUS register. Accordingly, in certain examples, such bits can provide the self-refresh status of the volatile memory.

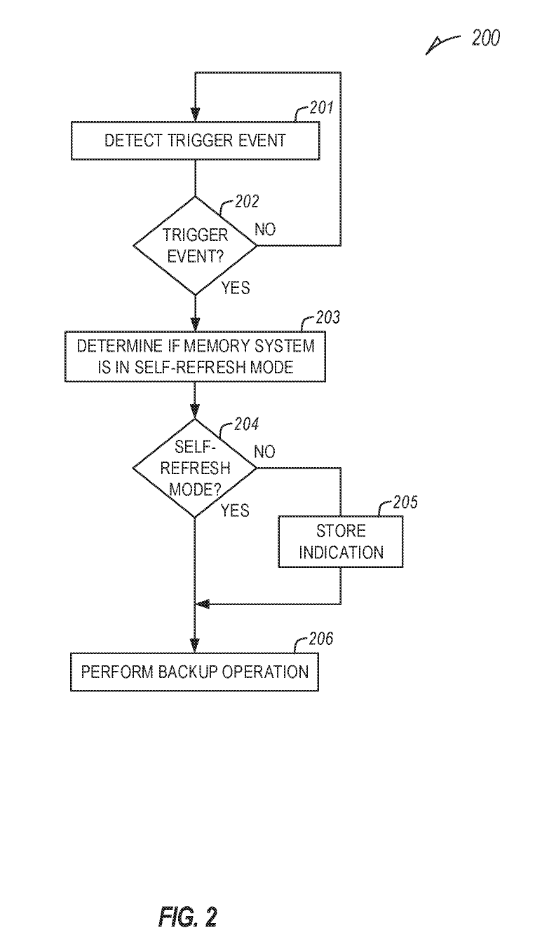

FIG. 2 illustrates an example method 200 of performing, using a processing device of a memory system, an internal backup operation on the memory system. The internal backup operation can include saving at least a portion of data stored on a group of volatile memory cells of the memory system to a group of non-volatile memory cells of the memory system in response to a trigger event and independent of a host-specific event.

At 201, a trigger event can be detected. The trigger event can include expiration of a timer implemented on the memory system. The host-specific event can include a command from a host (e.g., a save command, a self-refresh mode command, etc.). In other examples, the host-specific event can include loss of host power, an invalid host power (e.g., host power below a threshold to sustain host or memory system operation, etc.). In an example, the trigger event can include expiration of the timer while one or more of the following: host power is valid (e.g., above a threshold, etc); the processing device is not in self-refresh mode; or a state of a communication bus between the host and the memory system is unknown (e.g., to the memory system).

At 202, if a trigger event is not detected, process can return to 201, and the memory system can monitor for or detect a trigger event. At 202, if the trigger event is detected, then, at 203, the memory system can determine if the memory system is in a self-refresh mode. At 204, if the memory system is not in self-refresh mode, the memory system can, at 205, store an indication readable by a host that the memory system is not in self-refresh mode, such as in a register, then, at 206, perform an internal backup operation. At 204, if the memory system is in self-refresh mode, then, at 206, the memory system can perform the internal backup operation.

In certain examples, existing backup operations fail if the memory system is not in self-refresh mode. In contrast, storing an indication that the memory system is not in self-refresh mode and still performing a backup operation provide backup or recovery of information otherwise lost. In certain examples, at 204, if the memory system is not in self-refresh mode, the memory system can re-determine, in certain examples, after a period of time (e.g., after several clock cycles, milliseconds, seconds, etc.), if the memory system is in a self-refresh mode. After the memory system has re-determined that the memory system is not in self-refresh mode a number of times (e.g., 5, 10, 20, etc.), or after a period of time (e.g., a number of clock cycles, tens or hundreds of milliseconds, seconds, etc.), the process can proceed to 205.

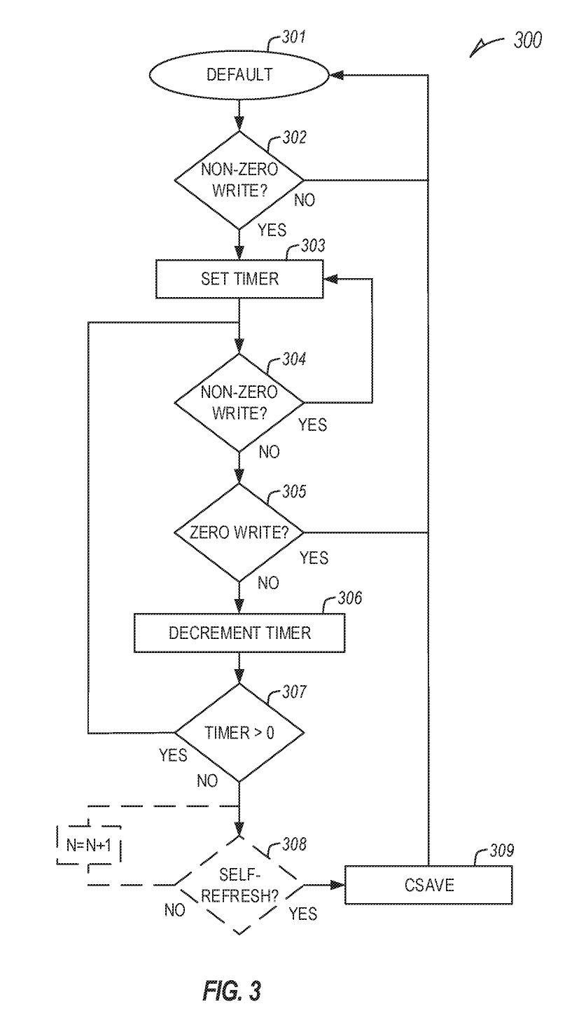

FIG. 3 illustrates an example method 300 for triggering a catastrophic save operation (CSAVE) in a memory system, such as a NVDIMM, using a timer. In an example, the timer can be implemented in the NVDIMM, such as using a timer register.

At 301, the timer register (e.g., a HOST_TIMEOUT_CSAVE_TIMEOUT register, etc.) implementing the timer can default to 0 at each reset, restart, power-on, or after a previous CSAVE event, etc. A memory controller (e.g., controller 125, processing device, etc.) can receive instructions from a host (e.g., a host 105), and can otherwise control implementation of the timer. A value of 0 effectively disables the timer.

At 302, if the timer register (or the memory controller) receives a non-zero write, the timer can be set to that value (e.g., between 1 and 255, etc.) at 303. At 302, if the timer register does not receive a non-zero write, the value of the timer can remain at 0, and process can return to 301. At any time in method 300, if the timer register receives a write of 0, process can return to 301, the value of the timer register can be set to 0, and the countdown timer can be stopped, without initiating a CSAVE. In an example, the memory controller (or logic associated with the memory controller) can write the values of the timer register.

At 304, if the timer register receives a non-zero write between 1 and 255, etc.), the timer can be set to that value at 303. If, at 304, the timer register does not receive a non-zero write, and at 305, the timer register does not receive a write of 0, then the value in the timer register can be decremented at 306, for example, using the memory controller. In an example, the memory controller can be configured to decrement the timer once per second. In other examples, other longer or shorter time periods can be used (e.g., the timer can be decremented every 20 milliseconds, 5 seconds, 10 seconds, etc., depending on the usage case of the memory system). If, at 305, the timer register receives a write of 0, the process can return to 301, the value of the timer register can be set to 0, and the countdown timer can be stopped.

At 307, if the value of the timer is greater than 0, then process can return to 304. At 307, if the timer expires (e.g., when the value of the timer is not greater than 0), a self-refresh mode of one or more component of the memory system (e.g., the memory controller, the volatile memory, the communication interface, etc.) can be checked at 308.

At 308, if the memory system or a component thereof (e.g., the memory controller, the volatile memory, the communication interface, etc.) is in a self-refresh mode, a CSAVE event can be triggered at 309. After the CSAVE event is triggered or complete, process can return to 301. In another example, the method 300 can ignore the state of the memory system or the communication interface. For example, if the volatile memory is not in self-refresh mode, but the timer expires at 307, a CSAVE event may still occur at 309 (e.g., omitting step 308).

At 308, if the memory system or a component thereof is not in self-refresh mode, one of several things can occur. In an example, an indication that the timer expired and the memory system or a component thereof was not in self-refresh mode can be stored, such as by the memory controller, for example, in a self-refresh register, and the CSAVE event can still be triggered. In an example, the indication that the volatile memory was not in self-refresh mode can be stored using a DRAM_NOT_SELF_REFRESH bit in a MODULE_HEALTH_STATUS0 register. Further, to continue with the CSAVE event, the NVM_DATA_VALID bit in the CSAVE_INFO register can be cleared.

In another example, the memory controller can wait for a period of time (e.g., 10 milliseconds, 1 second, a number of clock cycles, etc.), then recheck (e.g., n=n+1) for self-refresh mode. The number of times that self-refresh is rechecked (e.g., X times), and the period of time the memory controller waits before re-checking or between re-checks, can be default amounts, resettable, or programmable, for example, similar to the timer, described above. After a number of failed re-checks (e.g., X times), either the CSAVE event can be triggered at 309, or process can return to 301 without triggering a CSAVE event. For either outcome, an indication of failed re-checks can be stored (e.g., in a re-check register) for later reference, diagnosis, or characterization of memory system behavior.

In an example, at any point in the method 300, any read of the timer register can return the current value of the register, which, in certain examples, corresponds to the number of seconds remaining until the memory system initiates the CSAVE event. Further, in certain examples, the method 300 can ignore whether the memory system is armed to perform a CSAVE operation, and perform the CSAVE regardless of arm status of the memory system, as long as the memory system has the capability to perform a CSAVE operation.

In certain examples, the method 300 can be disabled during firmware updates, such as when the host or the memory system are receiving a firmware update. If the timer is running and a firmware update mode is enabled, the memory system can stop the timer and disable a CSAVE event. In an example, once the firmware update is complete, the previous state of the timer is not restored, but remains disabled until restarted or set, such as described above.

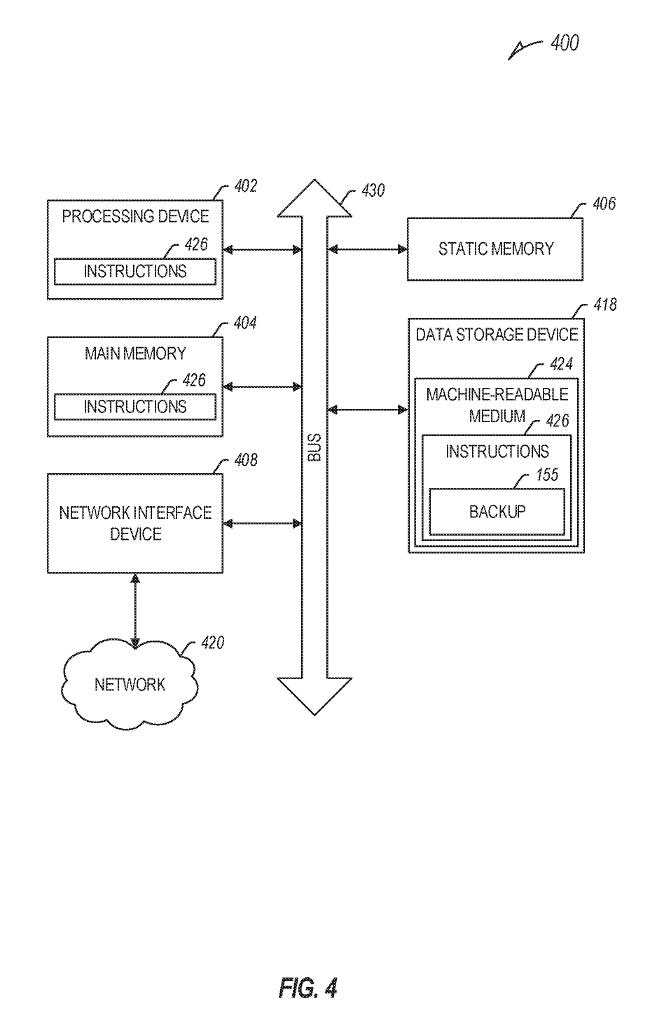

FIG. 4 illustrates an example machine of a computer system 400 within which a set of instructions, for causing the machine to perform any one or more of the methodologies discussed herein, can be executed. In some implementations, the computer system 400 can correspond to a host system (e.g., the host system 120 of FIG. 1) that includes or utilizes a memory system (e.g., the memory system 110 of FIG. 1) or can be used to perform the operations of a controller (e.g., to execute an operating system to perform operations corresponding to a backup or save operation such as described herein). In alternative implementations, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random-access memory (DRAM) such as synchronous DRAM (SDRAM) or Rambus DRAM (RDRAM), etc.), a static memory 406 (e.g., flash memory, static random-access memory (SR AM), etc.), and a data storage system 418, which communicate with each other via a bus 430.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions or software 426 embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory system 110 of FIG. 1.

In one implementation, the instructions 426 include a backup component 155 to implement functionality corresponding to backup operations, such as on a non-volatile dual in-line memory module (NVDIMM) memory system described above. While the machine-readable storage medium 424 is shown in an example implementation to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMS), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some implementations, a machine-readable (e.g., computer-readable) medium includes a machine (e.g., a computer) readable storage medium such as a read only memory (“ROM”), random access memory (“RAM”), magnetic disk storage media, optical storage media, flash memory systems, etc.

In the foregoing specification, implementations of the disclosure have been described with reference to specific example implementations thereof. It will be evident that various modifications can be made thereto without departing from the broader spirit and scope of implementations of the disclosure as set forth in the following claims. The specification and drawings are, accordingly, to be regarded in an illustrative sense rather than a restrictive sense.

### EXAMPLES

An example (e.g., “Example 1”) of subject matter (e.g., a system) can include a memory device comprising: a group of volatile memory cells; a group of non-volatile memory cells; and a processing device operably coupled to the group of volatile memory cells and the group of non-volatile memory cells, the processing device configured to perform internal backup operations in response to a trigger event, the internal backup operations comprising: determining, in response to the trigger event, if the memory system is in self-refresh mode; and in response to determining that the memory system is not in self-refresh mode: storing an indication readable by a host that the memory system is not in self-refresh mode; and performing an internal backup operation, comprising saving at least a portion of data stored on the group of volatile memory cells to the group of non-volatile memory cells.

In Example 2, the subject matter of Example 1 can optionally be configured such that the trigger event comprises expiration of a timer.

In Example 3, the subject matter of any one or more of Examples 1-2 can optionally be configured such that the processing device is configured to receive commands from the host and the timer is resettable by the host.

In Example 4, the subject matter of any one or more of Examples 1-3 can optionally be configured such that the processing device is configured to receive host power from the host and the trigger event comprises expiration of the timer while the host power is valid.

In Example 5, the subject matter of any one or more of Examples 1-4 can optionally be configured such that the trigger event comprises a save command

In Example 6, the subject matter of any one or more of Examples 1-5 can optionally be configured such that the internal backup operations comprise: storing, in a first register, an indication readable by a host that the memory system is capable to perform the internal backup operations; and storing, in a second register, upon performing the internal backup operation in response to the trigger event, an indication readable by the host that the memory system has performed the internal backup operation.

In Example 7, the subject matter of any one or more of Examples 1-6 can optionally be configured such that storing the indication that the memory system is not in self-refresh mode comprises storing the indication readable by the host that the memory system is not in self-refresh mode in a third register.

In Example 8, the subject matter of any one or more of Examples 1-7 can optionally be configured such that determining if the memory system is in self-refresh mode comprises determining if the volatile group of memory cells is in self-refresh mode.

An example (e.g., “Example 9”) of subject matter (e.g., a method) can comprise: performing internal backup operations in a memory system in response to a trigger event, the internal backup operations comprising: determining, in response to the trigger event, if the memory system is in self-refresh mode using a processing device of the memory system; and in response to determining that the memory system is not in self-refresh mode: storing an indication readably by a host that the memory system is not in self-refresh mode; and performing an internal backup operation, comprising saving at least a portion of data stored on a group of volatile memory cells of the memory system to the group of non-volatile memory cells of the memory system.

In Example 10, the subject matter of Example 9 can optionally be configured such that the trigger event comprises expiration of a timer.

In Example 11, the subject matter of any one or more of Examples 9-10 can optionally be configured to comprise receiving, using the processing device, commands from the host, wherein the timer is resettable by the host.

In Example 12, the subject matter of any one or more of Examples 9-11 can optionally be configured to comprise receiving power from the host, wherein the trigger event comprises expiration of the timer while the host power is valid.

In Example 13, the subject matter of any one or more of Examples 9-12 can optionally be configured such that the trigger event comprises a save command.

In Example 14, the subject matter of any one or mare of Examples 9-13 can optionally be configured to comprise: storing, in a first register, using the processing device, an indication readable by the host that the memory system is capable to perform the internal backup operations; and storing, in a second register, using the processing device, upon performing the internal backup operation in response to the trigger event, an indication that the memory system has performed the internal backup operation.

In Example 15, the subject matter of any one or more of Examples 9-14 can optionally be configured such that storing the indication that the memory system is not in self-refresh mode comprises storing the indication readable by the host that the memory system is not in self-refresh mode in a third register.

In Example 16, the subject matter of any one or more of Examples 9-15 can optionally be configured such that determining if the memory is in self-refresh mode comprises determining if the volatile group of memory cells is in self-refresh mode.

An example (e.g., “Example 17”) of subject matter (e.g., non-transitory computer-readable storage medium) can comprise instructions that, when executed by a processing device, cause the processing device to: perform internal backup operations in a memory system in response to a trigger event, the internal backup operations comprising: determine, in response to the trigger event, if the memory system is in self-refresh mode; and in response to determining that the memory system is not in self-refresh mode: store an indication readable by a host that the memory system is not in self-refresh mode; and perform an internal backup operation, comprising saving at least a portion of data stored on the group of volatile memory cells to the group of non-volatile memory cells.

In Example 18, the subject matter of Example 17 can optionally be configured such that the trigger event comprises expiration of a timer.

In Example 19, the subject matter of any one or more of Examples 17-18 can optionally be configured such that the instructions further comprise: receive commands from a host, wherein the timer is resettable by the host.

In Example 20, the subject matter of any one or mare of Examples 17-19 can optionally be configured such that the instructions further comprise: receive power from the host at the memory system, wherein the trigger event comprises expiration of the timer while the host power is valid.

An example (e.g., “Example 21”) of subject matter (e.g., a system or apparatus) can optionally combine any portion or combination of any portion of any one or more of Examples 1-20 to comprise “means for” performing any portion of any one or more of the functions or methods of Examples 1-20, or a “machine-readable medium” (e.g., non-transitory, etc.) comprising instructions that, when performed by a machine, cause the machine to perform any portion of any one or more of the functions or methods of Examples 1-20.

The above description is intended to be illustrative, and not restrictive. For example, the above-described examples (or one or more aspects thereof) may be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A memory system comprising.
a group of volatile memory cells;
a group of non-volatile memory cells; and
a processing device operably coupled to the group of volatile memory cells and the group of non-volatile memory cells, the processing device configured to perform internal backup operations in response to a trigger event, the internal backup operations comprising:
determining, in response to the trigger event, if the memory system is in self-refresh mode; and
in response to determining that the memory system is not in self-refresh mode:
storing an indication readable by a host that the memory system is not in self-refresh mode; and
performing an internal backup operation, comprising saving at least a portion of data stored on the group of volatile memory cells to the group of non-volatile memory cells.

2. The memory system of claim 1, wherein the trigger event comprises expiration of a timer.

3. The memory system of claim 2, wherein the processing device is configured to receive commands from the host, and
wherein the timer is resettable by the host.

4. The memory system of claim 3, wherein the processing device is configured to receive host power from the host, and
wherein the trigger event comprises expiration of the timer while the host power is valid.

5. The memory system of claim 1, wherein the trigger event comprises a save command.

6. The memory system of claim 1, wherein the internal backup operations comprise:
storing, in a first register, an indication readable by a host that the memory system is capable to perform the internal backup operations; and
storing, in a second register, upon performing the internal backup operation in response to the trigger event, an indication readable by the host that the memory system has performed the internal backup operation.

7. The memory system of claim 1, wherein storing the indication that the memory system is not in self-refresh mode comprises storing the indication readable by the host that the memory system is not in self-refresh mode in a third register.

8. The memory system of claim 1, wherein determining if the memory system is in self-refresh mode comprises determining if the volatile group of memory cells is in self-refresh mode.

9. A method, comprising:
performing internal backup operations in a memory system in response to a trigger event, the internal backup operations comprising:
determining, in response to the trigger event, if the memory system is in self-refresh mode using a processing device of the memory system; and
in response to determining that the memory system is not in self-refresh mode:
storing an indication readably by a host that the memory system is not in self-refresh mode; and
performing an internal backup operation, comprising at least a portion of data stored on a group of volatile memory cells of the memory system to the group of non-volatile memory cells of the memory system.

10. The method of claim 9, wherein the trigger event comprises expiration of a timer.

11. The method of claim 10, comprising:
receiving, using the processing device, commands from the host,
wherein the timer is resettable by the host.

12. The method of claim 11, comprising:
receiving power from the host,
wherein the trigger event comprises expiration of the timer while the host power is valid.

13. The method of claim 9, wherein the trigger event comprises a save command.

14. The method of claim 9, comprising:
storing, in a first register, using the processing device, an indication readable by the host that the memory system is capable to perform the internal backup operations; and
storing, in a second register, using the processing device, upon performing the internal backup operation in response to the trigger event, an indication that the memory system has performed the internal backup operation.

15. The method of claim 14, wherein storing the indication that the memory system is not in self-refresh mode comprises storing the indication readable by the host that the memory system is not in self-refresh mode in a third register.

16. The method of claim 9, wherein determining if the memory is in self-refresh mode comprises determining if the volatile group of memory cells is in self-refresh mode.

17. A non-transitory computer-readable storage medium comprising instructions that, when executed by a processing device, cause the processing device to:
perform internal backup operations in a memory system in response to a trigger event, the internal backup operations comprising:
determine, in response to the trigger event, if the memory system is in self-refresh mode; and
in response to determining that the memory system is not in self-refresh mode:
store an indication readable by a host that the memory system is not in self-refresh mode; and
perform an internal backup operation, comprising saving at least a portion of data stored on the group of volatile memory cells to the group of non-volatile memory cells.

18. The non-transitory computer-readable storage medium of claim 17, wherein the trigger event comprises expiration of a timer.

19. The non-transitory computer-readable storage medium of claim 18, wherein the instructions further comprise:
receive commands from a host,
wherein the timer is resettable by the host.

20. The non-transitorycomputer-readable storage medium of claim 19, wherein the instructions further comprise:
receive power from the host at the memory system,
wherein the trigger event comprises expiration of the timer while the host power is valid.
